(19) United States
(12) Patent Application Publication
(10) Pub. No.: US 2026/0259088 A1
(43) Pub. Date: Sep. 3, 2026

(54) CAPACITANCE SENSOR

(71) Applicants: HONDA MOTOR CO., LTD., Tokyo (JP); The University of British Columbia, Vancouver (CA)

(72) Inventors: Ryusuke Ishizaki, Wako-shi (JP); Takeshi Osato, Wako-shi (JP); Chrysanthemum Morton, Vancouver (CA); Sadan Wani, Vancouver (CA); John D W Madden, Vancouver (CA); Jack Plant, Vancouver (CA)

(21) Appl. No.: 19/550,463

(22) Filed: Feb. 26, 2026

(30) Foreign Application Priority Data
Feb. 28, 2025 (JP) 2025-032162

(51) Int. Cl. G01L 1/14; H01G 5/011; H01G 5/013; H01G 5/18; H05K 1/02

(52) U.S. Cl. CPC G01L 1/142; H01G 5/011; H01G 5/0136; H01G 5/0138; H01G 5/18; H05K 1/0281; H05K 2201/10015; H05K 2201/10151

(57) ABSTRACT

A capacitance sensor includes: a board; a first electrode provided on the board; a flexible member fixed to the board; and a second electrode provided in the flexible member to face the first electrode with a gap between the second electrode and the first electrode and configured to detect a capacitance with the first electrode. The flexible member includes: an electrode inclusion portion including the second electrode in the electrode inclusion portion and having a gap between the electrode inclusion portion and a surface of the board; a pillar portion extending between the electrode inclusion portion and the board; and an overlap portion formed in the pillar portion passing through a through hole penetrating the board and overlapping an outer edge portion of the through hole on a second surface opposite to the first surface of the board.

### CROSS-REFERENCE TO RELATED APPLICATION

Priority is claimed on Japanese Patent Application No. 2025-032162, filed Feb. 28, 2025, the contents of which are incorporated herein by reference.

### BACKGROUND

### Field of the Invention

The present invention relates to a capacitance sensor.

### BACKGROUND

In realizing a robot hand having dexterity and power, a tactile sensor having high sensitivity, a wide dynamic range, and high durability is important. Accordingly, a capacitance tactile sensor having a flexible pillar structure for realizing high sensitivity and a wide dynamic range has been proposed (Japanese Unexamined Patent Application, First Publication No. 2024-086155 and Japanese Unexamined Patent Application, First Publication No. 2024-086156).

This tactile sensor is a capacitance tactile sensor in which a capacitor is formed by a flexible electrode and a pad on a board. Here, a flexible structure part is fixed to a board part by applying an adhesive to a pillar and a substrate surface.

The flexible electrode needs to be connected to a board such as a PCB in order to measure a capacitance, and electrical connection between the flexible electrode and the board is realized by using part of a flexible dielectric pillar as a flexible conductor pillar, applying a conductive adhesive to the pad on the board, and bonding the conductor pillar thereto in order to reduce the size of the whole sensor unit.

In the related art, a technique described in PCT International Publication No. WO 2020/080127 is known.

### SUMMARY

However, in the related art in which the flexible pillar structure is fixed to the board using an adhesive, when a large external force (particularly, a shearing force) is applied to the fixed part, it is likely that the pillar with the flexible structure will be peeled off from the board.

When the pillar with the flexible structure is peeled off from the board, the relative position between the pillar and the board is shifted. Accordingly, it is likely that the capacitance of a capacitor constituted by an electrode on the top of the pillar and the board pad will be shifted and a drift offset will occur, and thus it is unlikely that the capacitance can be measured. In addition, it is likely that an electrical connection between the board and the conductor pillar will be cut off and thus the capacitance cannot be measured. As a result, there is a problem in that the device may not function satisfactorily as a sensor.

When an amount of adhesive to be used is increased for strong bonding, that is, when a side surface of the pillar in addition to a bottom surface of an end of the pillar are fixed with an adhesive, it is possible that flexibility of the pillar near the bonded part will be insufficient, and sensor sensitivity will decrease. Therefore, there is room for improvement in the related art.

An object of one aspect of the present invention is to provide a capacitance sensor that can achieve:
1. preventing the flexible structure from peeling off even when a strong shearing force is applied to a sensor surface; and
2. maintaining a connection with as low resistance as possible without damaging the flexibility of the pillar near a bonded part.

According to a first aspect of the present invention, a capacitance sensor is provided including: a board; a first electrode provided on a first surface of the board; a flexible member fixed to the board and having elasticity; and a second electrode provided in the flexible member to face the first electrode with a gap between the second electrode and the first electrode and configured to detect a capacitance with the first electrode, wherein the flexible member includes: an electrode inclusion portion including the second electrode in the electrode inclusion portion and having a gap between the electrode inclusion portion and a surface of the board; a pillar portion extending between the electrode inclusion portion and the board; and an overlap portion formed in the pillar portion passing through a through hole penetrating the board and overlapping an outer edge portion of the through hole on a second surface opposite to the first surface of the board.

A second aspect is the capacitance sensor according to the first aspect, wherein the flexible member can be formed of a dielectric.

A third aspect is the capacitance sensor according to the first aspect, wherein the board can include a conductive portion, and the pillar portion can include a conductor connecting the second electrode and the conductive portion.

A fourth aspect is the capacitance sensor according to the first aspect, wherein the pillar portion can include a cover portion covering the outer edge portion of the through hole on the first surface of the board.

A fifth aspect is the capacitance sensor according to the third aspect, wherein the conductive portion can be provided on at least one of an inner circumferential surface of the through hole in the board, the outer edge portion of the through hole on the first surface of the board, and the outer edge portion of the through hole on the second surface of the board and can be electrically connected to the conductor of the pillar portion.

A sixth aspect is the capacitance sensor according to the first aspect, wherein the overlap portion can be formed either over an entire outer edge of the through hole or a part of the outer edge in a circumferential direction of the through hole.

A seventh aspect is the capacitance sensor according to the first aspect, wherein a plurality of pillar portions can be formed, and a plurality of through holes can be formed.

According to the first aspect, a part formed of a flexible member which is flexibly deformed to detect an external load is fixed to a board part having a certain degree of hardness such that the board part is not deformed at the time of detection using the through hole and the overlap portion. Accordingly, unlike a connected state using only an adhesive, even when a large external load is applied and the flexible member is deformed, the overlap portion does not depart from the through hole. This is because an anchor structure is provided in which a state in which the overlap portion is in contact with the outer edge of the through hole is maintained even when the flexible part is deformed by pulling.

Accordingly, since the overlap portion is a flexible member and is unified with a pillar (the pillar portion) which is deformed at the time of detection, the overlap portion is deformed along with the pillar but is not separated from the pillar when the flexible part is pulled. As a result, the flexible part is not separated from the board. Accordingly, a relative position between opposing electrodes serving as a pair forming a capacitor for detection is maintained. It is possible to prevent misalignment between the electrodes and to prevent a shift in the capacitance of the capacitor. The conductive portion serving as a wire portion allowing a detection current to flow and a conductor are not disconnected, and it is possible to maintain a detection operation even when a large external load is applied and to improve operation reliability of the sensor.

In addition, since connection using an adhesive is not used, deformation of the flexible member is not hindered, and deformation of the pillar portion which is a deformable member delivering the magnitude of an external load applied thereto as a change in relative position to the second electrode which is a detection portion is not affected. Accordingly, detection sensitivity is not decreased, and it is possible to perform accurate detection.

It is possible to increase the magnitude of an external load serving as a limit at which the flexible member locked to the board using the overlap portion is separated from the board and to increase the detection range of the sensor. Accordingly, it is possible to realize a tactile sensor having high sensitivity, a wide dynamic range, and high durability.

Here, the direction in which the external load is applied such that the flexible part is deformed and pulled includes a direction in which the flexible part is pressed to the board part, a direction parallel to the board surface, and an oblique direction in which these directions are combined in addition to a direction in which the flexible part is pulled off from the board part. This is because, when a large external load close to a limit or equal to or greater than the limit is applied, there is a likelihood that the flexible part will be separated from the board part regardless of the application direction of the external load.

The board is not limited to a plate shape such as a so-called PCB. For example, as long as the flexible member can be attached along a surface of an object having a certain volume, and an electrode and a through hole can be formed at the corresponding place, the capacitance sensor can be applied to any object to detect an external load such as a curved shape or an outer surface of a robot.

The first electrode has only to be disposed along the board surface, and the position in a thickness direction of the board is not limited. In this case, the conductive portion in the thickness direction of the board is provided.

A plurality of pillars (pillar portions) may be provided. In this case, a pillar portion with the overlap portion which is fixed and connected to the board has only to be provided, and the pillar may be provided without the overlap portion.

As the through hole, a hole provided in the board for forming a detection circuit may be used, or a hole provided in the board separately from the conductive portion to fix the flexible member may be used.

A part with which the overlap portion is in contact with the second surface of the board may be bonded.

According to the second aspect, the electrode inclusion portion holding the second electrode and a wire portion connected to the second electrode is formed of the flexible member, and the pillar portion connecting the wire portion and the board is formed of the flexible member. The flexible member serves as a support member for the wire portion and the deformable member converting the magnitude of the external load to the magnitude of deformation and delivering the magnitude of deformation as a change in relative position to the second electrode as a detection part. Accordingly, when an electrode position is changed along with the flexible member at the time of the external load detection, a structure for insulation other than the flexible member does not need to be provided. In addition, since the flexible member located between the second electrode and the first electrode is formed of a dielectric, it is possible to enhance the dielectric constant between two electrodes to increase the capacitance between the electrodes and to improve sensor sensitivity.

Similarly, when a conductor serving as a wire is formed in the pillar and the overlap portion, disconnection is not caused even when the flexible member and the conductor are deformed, and the insulated state of a circuit part can be maintained. Accordingly, it is possible to maintain a detection operation even when a large external load is applied and improve operation reliability of the sensor.

According to the third aspect, since the conductor is formed in the pillar portion formed of the flexible member, deformation of the pillar portion is not hindered by the conductor. Accordingly, it is possible to deliver a current (detection information) from the second electrode to the conductive portion without being affected by deformation of the pillar portion which is a deformable member converting the magnitude of the external load to the magnitude of deformation and delivering the magnitude of deformation as a change in relative position to the second electrode (detection part). As a result, detection accuracy of the sensor is not decreased. Since deformation of the pillar portion does not disturb the detection signal, it is possible to accurately detect the external load.

According to the fourth aspect, the front and rear surfaces of the outer edge surrounding the through hole can be interposed between the overlap portion and the cover portion. Accordingly, it is possible to prevent misalignment between the flexible member and the board and departure of the flexible member from the board. Since the overlap portion and the cover portion are in contact with the front and rear surfaces of the board, it is possible to reliably deliver a sensor detection signal by forming the conductor and the conductive portion in the corresponding part.

According to the fifth aspect, when an external load is applied, there is a likelihood that the flexible member will be deformed, the conductor of the flexible member will be separated from the conductive portion of the board, and electrical connection will be affected to decrease sensor detection accuracy, which can be prevented.

As a prerequisite, the second electrode and the conductor in the flexible member are formed by adding conductive powder to the flexible member material. Accordingly, when the conductor is compressed, electrical resistance decreases. In addition, a contact resistance between the pressed conductor and the conductive portion decreases.

When an external load is applied and the flexible member and the board are separated in the vicinity of the through hole, a part in the reverse direction to the direction in which the external load is applied with respect to the separated part is pressed. That is, even when a contact area in the separated part decreases and electrical resistance increases, the pressed part is compressed and the electrical resistance decreases. Accordingly, the separation between the flexible member and the board due to application of the external load is cancelled out, and delivery of a detection current is not hindered. As a result, it is possible to maintain the detection operation even when a large external load is applied, to increase a detectable range of the sensor, and to improve operation reliability of the sensor.

When the flexible member is compressed in the direction in which the external load is applied and the electrical resistance of the conductor at the corresponding position decreases, the total electrical resistance decreases as long as the part in the reverse direction to the direction in which the external load is applied is not peeled off.

According to the sixth aspect, when the overlap portion is formed on the whole outer edge of the through hole, the overlap portion is less likely to depart from the through hole, and it is possible to prevent misalignment of the flexible member from the board or separation of the flexible member from the board. When the overlap portion is formed in a part of the outer edge in the circumferential direction of the through hole, the area of the overlap portion in a plan view decreases, and thus it is possible to decrease the volume of the flexible member and to achieve a decrease in weight and space saving. Since the overlap portion has only to be fixed through the through hole when the flexible member with the overlap portion formed therein is unified with the board, it is possible to reduce the number of manufacturing steps.

Here, when the overlap portion is formed in only part of the outer edge of the through hole, a direction in which the overlap portion extends in the circumferential direction of the through hole can be preferably set to different directions in a plurality of pillar portions. Accordingly, even when some overlap portions depart from correct positions relative to the through holes due to an external load applied in one direction, the pillar portions including the overlap portions formed in other directions do not depart from the through holes, and it is possible to improve operation reliability of the sensor.

According to the seventh aspect, the overlap portions and/or the cover portions in a plurality of pillar portions can be formed in different shapes. Here, the different shapes include a state in which the overlap portion and/or the cover portion is not provided. In the plurality of pillar portions, a pillar portion which includes a conductor to maintain connection to the board and a pillar portion which does not include a conductor and which is only connected to the board can be mixed.

The through hole may relate to electrical connection such as a via-hole or a through-hole in a PCB or may have a configuration for only fixing the flexible member to the board.

According to the aspects of the present invention, it is possible to provide an advantage capable of realizing a tactile sensor having high sensitivity, a wide dynamic range, and high durability.

### BRIEF DESCRIPTION OF THE DRAWINGS

FIG. 1 is a sectional view schematically illustrating a capacitance sensor according to a first embodiment of the present invention.

FIG. 2 is an enlarged sectional view illustrating a principal part of the capacitance sensor according to the first embodiment of the present invention.

FIG. 3 is a top view illustrating a board surface in the capacitance sensor according to the first embodiment of the present invention.

FIG. 4 is a sectional view illustrating a state in which an external load is applied in a capacitance sensor according to the related art.

FIG. 5 is a sectional view illustrating a state in which an external load is applied in a capacitance sensor according to the related art.

FIG. 6 is a sectional view illustrating a state in which an external load is applied in the capacitance sensor according to the first embodiment of the present invention.

FIG. 7 is a sectional view illustrating a modified example of the capacitance sensor according to the first embodiment of the present invention.

FIG. 8 is a sectional view illustrating a modified example of the capacitance sensor according to the first embodiment of the present invention.

FIG. 9 is a sectional view illustrating a modified example of the capacitance sensor according to the first embodiment of the present invention.

FIG. 10 is a sectional view illustrating a modified example of the capacitance sensor according to the first embodiment of the present invention.

FIG. 11 is a sectional view illustrating a modified example of the capacitance sensor according to the first embodiment of the present invention.

FIG. 12 is an enlarged sectional view illustrating a capacitance sensor according to a second embodiment of the present invention.

FIG. 13 is an enlarged sectional view illustrating a state in which an external load is applied to the capacitance sensor according to the second embodiment of the present invention.

FIG. 14 is an enlarged sectional view illustrating a state in which an external load is applied to the capacitance sensor according to the second embodiment of the present invention.

FIG. 15 is an enlarged sectional view illustrating a state in which an external load is applied to the capacitance sensor according to the second embodiment of the present invention.

FIG. 16 is an enlarged sectional view illustrating a state in which an external load is applied to the capacitance sensor according to the second embodiment of the present invention.

FIG. 17 is an enlarged sectional view illustrating a state in which an external load is applied to the capacitance sensor according to the related art.

FIG. 18 is an enlarged sectional view illustrating a state in which an external load is applied to the capacitance sensor according to the second embodiment of the present invention.

FIG. 19 is an enlarged sectional view illustrating a state in which an external load is applied to the capacitance sensor according to the second embodiment of the present invention.

FIG. 20 is an enlarged sectional view illustrating a state in which an external load is applied to the capacitance sensor according to the second embodiment of the present invention.

FIG. 21 is an enlarged sectional view illustrating a state in which an external load is applied to the capacitance sensor according to the second embodiment of the present invention.

FIG. 22 is a graph illustrating a relationship between an external force and a resistance value in the capacitance sensor according to the embodiment of the present invention.

### DESCRIPTION OF EMBODIMENTS

Hereinafter, a capacitance sensor according to a first embodiment of the present invention will be described with reference to the accompanying drawings.

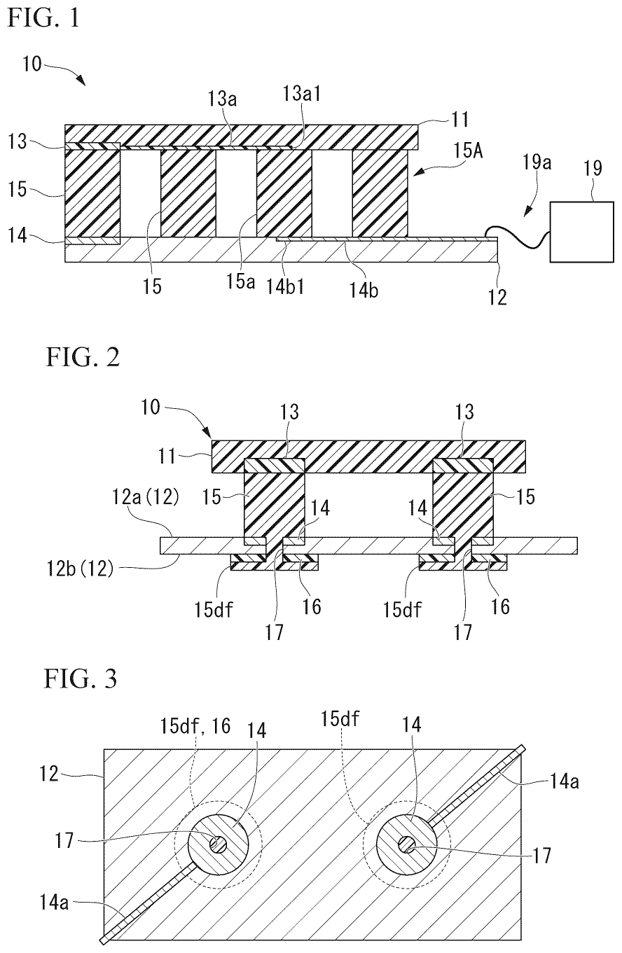

FIG. 1 is a sectional view schematically illustrating a capacitance sensor according to the present embodiment. FIG. 2 is an enlarged sectional view illustrating the capacitance sensor according to the present embodiment. FIG. 3 is a top view illustrating a board surface in the capacitance sensor according to the present embodiment. In the drawings, reference sign 10 denotes a capacitance sensor.

As illustrated in FIGS. 1 to 3, the capacitance sensor 10 according to the present embodiment includes an electrode inclusion portion 11, a board 12, a flexible electrode (a second electrode) 13, a flexible wire (a conductor) 13a, a board electrode (a first electrode) 14, board surface wires (board wires, conductive portions) 14a and 14b, a pillar (a pillar portion) 15, a pillar wire (a flexible wire, a conductor) 15a, an overlap portion 15df, a through hole 17, and a control unit 19.

The electrode inclusion portion 11 is disposed along a surface (a first surface) 12a of the board 12. The electrode inclusion portion 11 is disposed to face the surface 12a of the board 12. The electrode inclusion portion 11 is disposed to be substantially parallel to the surface 12a of the board 12. The electrode inclusion portion 11 is separated from the surface 12a of the board 12. The electrode inclusion portion 11 is formed of a flexible member 15A which will be described later. The electrode inclusion portion 11 includes a plurality of flexible electrodes 13 and a plurality of flexible wires 13a.

The board 12 has a plate shape. The board 12 may be a rigid board such as a printed board. The board 12 may be a flexible board. The board 12 is not limited to the plate shape as long as a flexible portion formed of the flexible member 15A can be fixed to the surface 12a and the through hole 17 can be formed. The board 12 may have a planar shape or a curved shape. The board 12 may have a thickness which is fixed or not fixed. The board 12 may be formed of a material which is harder than the flexible member 15A which will be described later. The board 12 is formed of a material which can cover a range in which deformation of the flexible portion formed of the flexible member 15A can be detected at the time of detection of an external force F which will be described later. In the board 12, a plurality of board electrodes 14 and a plurality of board surface wires (board wires) 14a and 14b are disposed along the surface 12a. The board wires 14a and 14b are connected to the control unit 19. The board wires 14a and 14b may be connected to the control unit 19 via a connection line 19a.

The flexible electrode 13 is a transmission electrode. A plurality of flexible electrodes 13 are disposed substantially on the same plane. The plurality of flexible electrodes 13 are located in the same layer. The same layer means that the plurality of flexible electrodes 13 are disposed at almost the same distance from the surface 12a of the board 12. The plurality of flexible electrodes 13 are separated from each other.

The plurality of flexible electrodes 13 have almost the same contour shape. The plurality of flexible electrodes 13 have the same area. In a plan view, the distance between the neighboring flexible electrodes 13 is constant. The flexible electrode 13 is connected to the flexible wire 13a. Each flexible electrode 13 is connected to the control unit 19 via the flexible wire 13a and a pillar wire 15a and a board surface wire 14b which will be described later.

The flexible electrodes 13 face the board electrodes 14. The flexible electrodes 13 correspond to the board electrodes 14. In a plan view, the flexible electrodes 13 are disposed to overlap the board electrodes 14.

The board electrode 14 is a reception electrode. A plurality of board electrodes 14 are disposed along the surface 12a of the board 12. The plurality of board electrodes 14 are disposed substantially on the same plane. The plurality of board electrodes 14 are located in the same layer. The plurality of board electrodes 14 are separated from each other. The plurality of board electrodes 14 have almost the same contour shape. The plurality of board electrodes 14 have almost the same area. In a plan view, a distance between the neighboring board electrodes 14 is constant. In a plan view, the separation distance between the neighboring board electrodes 14 is equal to the distance between the neighboring flexible electrodes 13. Each board electrode 14 is connected to the board wire 14b. Each board electrode 14 is connected to the control unit 19 via the board wire 14b.

The pillar 15 connects the electrode inclusion portion 11 and the board 12 in a stacking direction. Both ends of the pillar 15 are connected to the electrode inclusion portion 11 and the board 12. A plurality of pillars 15 are formed on the surface 12a of the board 12. The plurality of pillars 15 are separated from each other. The plurality of pillars 15 have almost the same sectional contour shape in a plan view. The plurality of pillars 15 have almost the same area. The plurality of pillars 15 have almost the same sectional shape in the whole length in an axial direction parallel to the direction in which they are separated from the surface 12a of the board 12. In a plan view, distances between the neighboring pillars 15 are the same.

The sectional contour shape of the pillar 15 in a plan view may be the same as the contour shape of the flexible electrode 13. The sectional contour shape of the pillar 15 in a plan view may be larger than the contour shape of the flexible electrode 13.

In a plan view, the distance between the neighboring pillars 15 may be equal to the distance between the neighboring flexible electrodes 13. In a plan view, the distance between the neighboring pillars 15 may be larger than the distance between the neighboring flexible electrodes 13. In a plan view, the distance between the neighboring pillars 15 may be smaller than the distance between the neighboring flexible electrodes 13.

The pillar wire 15a electrically connecting the electrode inclusion portion 11 and the board 12 in the stacking direction is formed in the pillar 15. The pillar wire 15a electrically connects the flexible wire 13a and the board surface wire 14b.

The electrode inclusion portion 11 and the pillar 15 are formed of a dielectric or a flexible elastomer which can be elastically deformed. The electrode inclusion portion 11 and the pillar 15 are formed of the flexible member 15A which is the same material. The electrode inclusion portion 11 and the pillar 15 are formed as a unified body.

The flexible member 15A is formed of, for example, silicone rubber, gel of polyvinylchloride (PV), or a flexible dielectric including polyvinylidene fluoride (PVDF), polydimethylsiloxane (PDMS), silicon-based resin, an urethane resin, an epoxy-based resin, a styrene-based resin, or a composite material thereof. For example, a material with a dielectric constant of about ε=1.4 F/m can be selected as the flexible member 15A. The flexible member 15A may have material characteristics indicating hyperelasticity, flexibility, elasticity, and a material containing gas which is a material containing a fluid or bubbles.

All of the flexible electrode 13, the flexible wire 13a, and the pillar wire 15a are formed of a conductor having elasticity. The flexible electrode 13, the flexible wire 13a, and the pillar wire 15a can be formed of a material having an additive for changing the conductivity or the dielectric constant to the same flexible member 15A as the electrode inclusion portion 11 and the pillar 15. The wires connected to the flexible electrode 13, the flexible wire 13a, and the pillar wire 15a can be formed of the same material. The flexible electrode 13, the flexible wire 13a, and the pillar wire 15a may be formed, for example, by mixing conductive powder into the flexible member 15A.

The flexible electrode 13, the flexible wire 13a, and the pillar wire 15a may be formed of a silicon-based resin with a conductor mixed thereinto such as carbon, carbon nano fiber, or graphite, a silicon-based resin containing metallic conductive fillers such as silver or copper, a conductive resin such as thiophene-based conductive polymer or polystyrene sulfonate (PSS), or a composite material thereof.

The board electrode 14 and the board wires 14a and 14b are formed of a metal, a conductive resin, or the like.

The control unit 19 is connected to the flexible electrode 13 and the board electrode 14. The control unit 19 can detect a capacitance between the flexible electrode 13 and the board electrode 14.

The through hole 17 is formed in the board 12. The through hole 17 penetrates the board 12 from the surface 12a of the board 12 to the rear surface 12b (the second surface). The through hole 17 is formed at a position overlapping the pillar 15 in a plan view. The through hole 17 may have the same diameter as the pillar 15. The through hole 17 may have a diameter smaller than that of the pillar 15. The through hole 17 may be formed at a position not overlapping the pillar 15 in a plan view.

An end of the pillar 15 connected to the board 12 extends into the through hole 17. The pillar 15 extends to the rear surface 12b of the board 12. An overlap portion 15df is formed in the pillar 15 located on the rear surface 12b of the board 12. The overlap portion 15df is a part overlapping the board 12 when seen in the normal direction of the board 12.

The overlap portion 15df is in contact with the outer edge of the through hole 17 on the rear surface 12b of the board 12.

The overlap portion 15df is present at the outer edge of the through hole 17 along the rear surface 12b of the board 12. The overlap portion 15df is formed in a flange shape with an enlarged diameter with respect to the pillar 15. The overlap portion 15df is formed in a flange shape with an enlarged diameter with respect to the through hole 17.

When the diameter of the through hole 17 is smaller than the diameter of the pillar 15, the diameter of the overlap portion 15df may be the same as the pillar 15.

The diameter of the overlap portion 15df is larger than the diameter of the through hole 17. The diameter of the overlap portion 15df is larger than the diameter of the pillar 15.

The overlap portion 15df has the same thickness in the circumferential direction. The overlap portion 15df has the same thickness in the radial direction. The overlap portion 15df is formed as a unified body with the pillar 15. The overlap portion 15df is formed of the flexible member 15A which is the same material as the pillar 15. When a flexible pillar wire 15a is formed in the pillar 15, the overlap portion 15df may include a part formed of the same material as the pillar wire 15a.

The overlap portion 15df may be bonded to the rear surface 12b of the board 12 using an adhesion portion 16. The overlap portion 15df is bonded to the rear surface 12b of the board 12 using the adhesion portion 16 in all the pillars 15. The overlap portion 15df may not be bonded to the rear surface 12b of the board 12.

In the capacitance sensor 10 according to the present embodiment, in a state in which an external load F is not applied, an area in which the flexible electrode 13 and the board electrode 14 overlap in a plan view is S.

In the state in which an external force F is not applied, a distance between the flexible electrode 13 and the board electrode 14 is d. When a capacitance between the flexible electrode 13 and the board electrode 14 in the state in which an external force F is not applied is C, the capacitance C is expressed by the following expression.

$$C = ε \cdot S / d$$

When an external load F is applied, the electrode inclusion portion 11 and the pillar 15 are deformed. The pillar 15 is deformed to correspond to the direction of the external load F.

When the external load F is applied in a direction in which the flexible electrode 13 and the board electrode 14 are compressed, the inter-electrode distance d between the flexible electrode 13 and the board electrode 14 changes to decrease. Alternatively, when the external load F is applied in a direction in which the flexible electrode 13 and the board electrode 14 are separated from each other, the inter-electrode distance d between the flexible electrode 13 and the board electrode 14 changes to increase similarly.

In this case, the capacitance between the flexible electrode 13 and the board electrode 14 changes. By detecting this change in capacitance, it is possible to measure the external load F.

Alternatively, when an external load F is applied in a direction parallel to the surface 12a of the board 12, the flexible electrode 13 is shifted with respect to the board electrode 14, and the area S in which the flexible electrode 13 overlaps the board electrode 14 changes to an area S-A. Then, the capacitance C between the flexible electrode 13 and the board electrode 14 changes. By detecting this change in capacitance, it is possible to measure the external load F.

An external load F may be applied in an oblique direction in addition to the normal direction of the surface 12a of the board 12 and the direction parallel to the surface 12a of the board 12. In this case, the change of the inter-electrode distance d and the change of the overlapping area S occur at the same time. Then, the capacitance C between the flexible electrode 13 and the board electrode 14 changes similarly. By detecting this change in capacitance, it is possible to measure the external load F.

The state in which an external load is applied to the capacitance sensor will be described below.

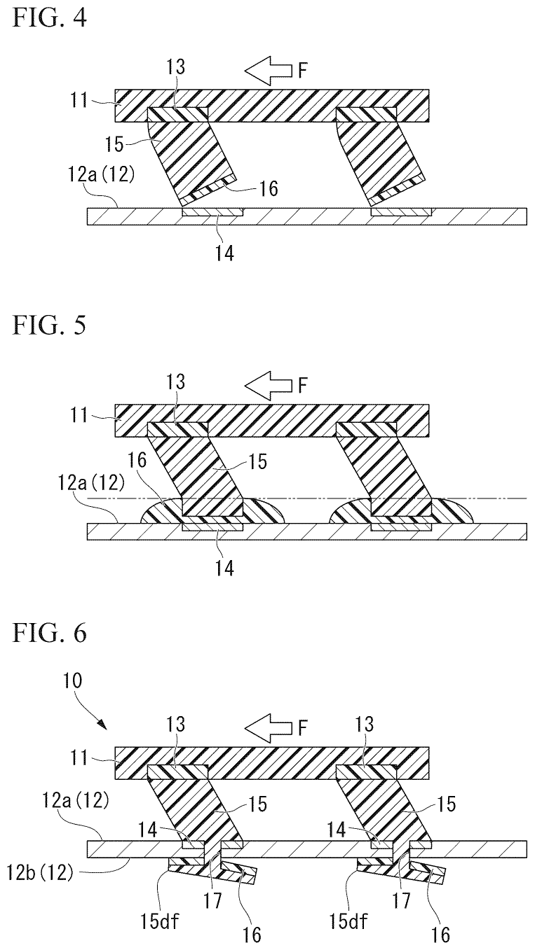

FIG. 4 is a sectional view schematically illustrating a state in which an external load is applied to a capacitance sensor according to the related art. In FIG. 4, the state in which an external load F is applied leftward along the surface 12a of the board 12 is illustrated.

In a structure according to the related art in which the through hole 17 and the overlap portion 15df are not provided and the end face of the pillar 15 is bonded to the surface 12a of the board 12 using the adhesion portion 16, when a large external load F is applied, the adhesion portion 16 peels off from the surface 12a of the board 12 as illustrated in FIG. 4, and the flexible electrode 13 and the board electrode 14 cannot return to the position before the external load F is applied. Accordingly, it is not possible to perform accurate detection even when an external load F is applied again.

FIG. 5 is a sectional view schematically illustrating a state in which an external load is applied to a capacitance sensor according to the related art. In FIG. 5, a state in which an external load F is applied leftward along the surface 12a of the board 12 is illustrated.

Similarly, in the structure according to the related art in which side faces of the end of the pillar 15 in addition to the end face are bonded to the surface 12a of the board 12 using the adhesion portion 16, when an external load F is applied, only part of the pillar 15 in which the adhesion portion 16 is not provided can be deformed as illustrated in FIG. 5. Accordingly, the change in relative position between the flexible electrode 13 and the board electrode 14 due to the applied external load F decreases, the sensor sensitivity deteriorates.

FIG. 6 is a sectional view schematically illustrating a state in which an external load is applied to the capacitance sensor according to the present embodiment. In FIG. 6, a state in which an external load F is applied leftward along the surface 12a of the board 12 is illustrated.

In comparison with the structure according to the related art, when an external load F is applied to the capacitance sensor 10 according to the present embodiment as illustrated in FIG. 6, a part formed of the flexible member 15A is deformed with respect to the board 12.

When the applied external load F is larger than a predetermined value, the amount of deformation increases, and a shearing force is applied to a connection part between the flexible member 15A and the board 12, that is, a part in which the pillar 15 is in contact with the board 12. Here, the overlap portion 15df of the pillar 15 is formed on the rear surface 12b of the board 12. Since the overlap portion 15df is wider than the through hole 17, an anchor structure is provided, and thus the pillar 15 does not depart from the through hole 17.

Accordingly, when the applied external load F is removed, the deformation of the flexible member 15A is released, and the positions of the flexible electrode 13 and the board electrode 14 return to the positions before the external load F has been applied.

Accordingly, the capacitance C returns to the original state. As a result, even when an external load F is applied again, the value of the capacitance C between the flexible electrode 13 and the board electrode 14 is not shifted, and it is possible to prevent occurrence of drift offset and to perform accurate detection.

Particularly, when the overlap portion 15df is bonded to the rear surface 12b of the board 12 using the adhesion portion 16, there is a likelihood that the overlap portion 15df located at a position on the reverse side to the direction in which an external load F is applied will be peeled off from the rear surface 12b due to a large external load F. In this case, since the overlap portion 15df on the forward side in the direction in which the external force F is applied is bonded to the rear surface 12b, the pillar 15 does not depart from the through hole 17. Accordingly, when the applied external load F is removed, the deformation of the flexible member 15A is released, and the positions of the flexible electrode 13 and the board electrode 14 return to the positions before the external load F has been applied. As a result, the capacitance C returns to the original state. Accordingly, it is possible to perform accurate detection even when an external load F is applied again.

At this time, when the overlap portion 15df does not depart from the pillar 15 due to the shearing fore, the positions of the flexible electrode 13 and the board electrode 14 can be returned, and the capacitance sensor 10 according to the present embodiment can exhibit high durability. Accordingly, it is possible to extend the sensor detection range to correspond to a large external load F.

When the capacitance sensor 10 according to the present embodiment is manufactured, a board 12 in which the through holes 17, the board electrodes 14, and the board wires 14a and 14b are formed is prepared. An electrode inclusion portion 11 including the flexible electrode 13 and the flexible wire 13a is formed using the flexible member 15A. At this time, after a plate body formed of the flexible member 15A and including recessed parts corresponding to the flexible electrode 13 and the flexible wire 13a has been shaped using a mold, the flexible electrode 13 and the flexible wire 13a can be formed using the flexible member 15A in which conductive particles are mixed into the recessed parts of the plate body. Alternatively, the flexible electrode 13 and the flexible wire 13a having predetermined shapes are first formed at predetermined positions, and then the electrode inclusion portion 11 may be formed as a unified body to cover the flexible electrode 13 and the flexible wire 13a.

Then, the pillar 15 and the pillar wire 15a are formed to form a unified body along with the electrode inclusion portion 11 including the flexible electrode 13 and the flexible wire 13a using a mold corresponding to the pillar 15. The pillar 15 and the pillar wire 15a may be formed using other steps and other molds similarly to the flexible electrode 13 and the flexible wire 13a.

Then, the end of the pillar 15 is brought into contact with the board 12 and is aligned with the corresponding through hole 17.

The inner part of the through hole 17 and the overlap portion 15df are formed of the flexible member 15A to extend continuously from the end of the pillar 15. At this time, the adhesion portion 16 can be formed before the overlap portion 15df is formed.

As a result, the capacitance sensor 10 is manufactured.

The capacitance sensor 10 according to the present embodiment can be embodied in the following modified examples.

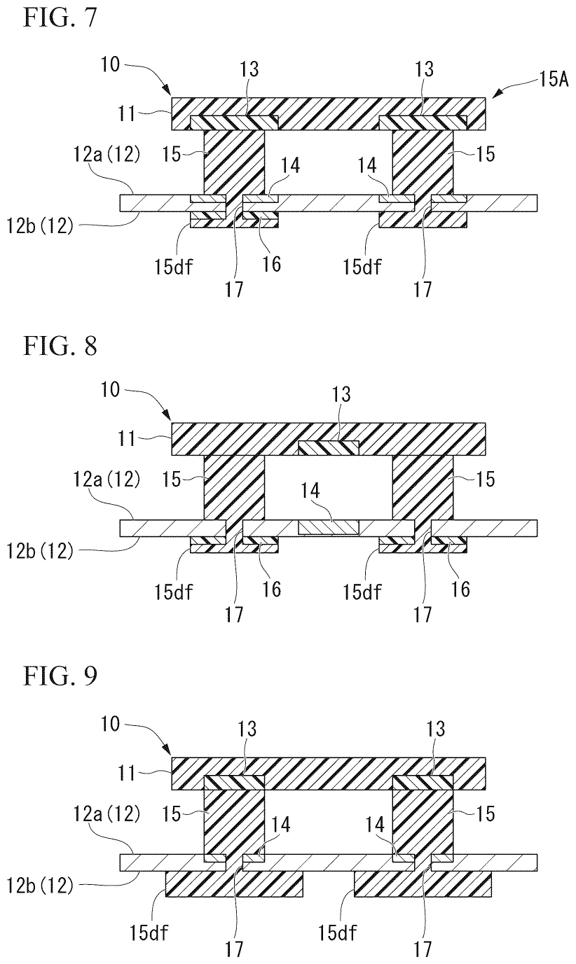

FIG. 7 is a sectional view schematically illustrating a modified example of the capacitance sensor according to the present embodiment.

In this modified example, in the left pillar 15, the overlap portion 15df is bonded to the to the rear surface 12b of the board 12 via the adhesion portion 16 as illustrated in FIG. 7. On the other hand, in the right pillar 15, the overlap portion 15df is directly connected to the rear surface 12b of the board 12, and the adhesion portion 16 is not provided. Here, the adhesion portion 16 is formed in the whole contact surface area in which the overlap portion 15df is in contact with the rear surface 12b of the board 12.

In this modified example, in a top view, the contour shape of the flexible electrode 13 is larger than the contour shape of the pillar 15. In a top view, the contour shape of the flexible electrode 13 is larger than the contour shape of the through hole 17.

In a top view, the contour shape of the flexible electrode 13 has the same size as the contour shape of the overlap portion 15df.

FIG. 8 is a sectional view schematically illustrating a modified example of the capacitance sensor according to the present embodiment.

In this modified example, the board electrode 14 is formed at a position different from that of the through hole 17 as illustrated in FIG. 8. In this example, in the pillar 15 fixed to the through hole 17 via the overlap portion 15df, the board electrode 14 and the board wires 14a and 14b are not in contact with the through hole 17. In addition, the overlap portion 15df is not in contact with the board substrate 14, the board wires 14a and 14b, and the through hole 17.

FIG. 9 is a sectional view schematically illustrating a modified example of the capacitance sensor according to the present embodiment.

In this modified example, the ratio of the contour shape of the overlap portion 15df to the contour shape of the pillar 15 is higher than that of the configuration illustrated in FIGS. 2 and 6 as illustrated in FIG. 9. That is, the contour shape of the overlap portion 15df with respect to the through hole 17 is larger than that of the configuration illustrated in FIGS. 2 and 6. The thickness of the overlap portion 15df is larger than that of the configuration illustrated in FIGS. 2 and 6. This modified example can be applied to a case in which a large space can be secured on the rear surface 12b of the board 12, that is, a case in which the thickness of the sensor can be set to be large, or a case in which the thickness of the board 12 is large.

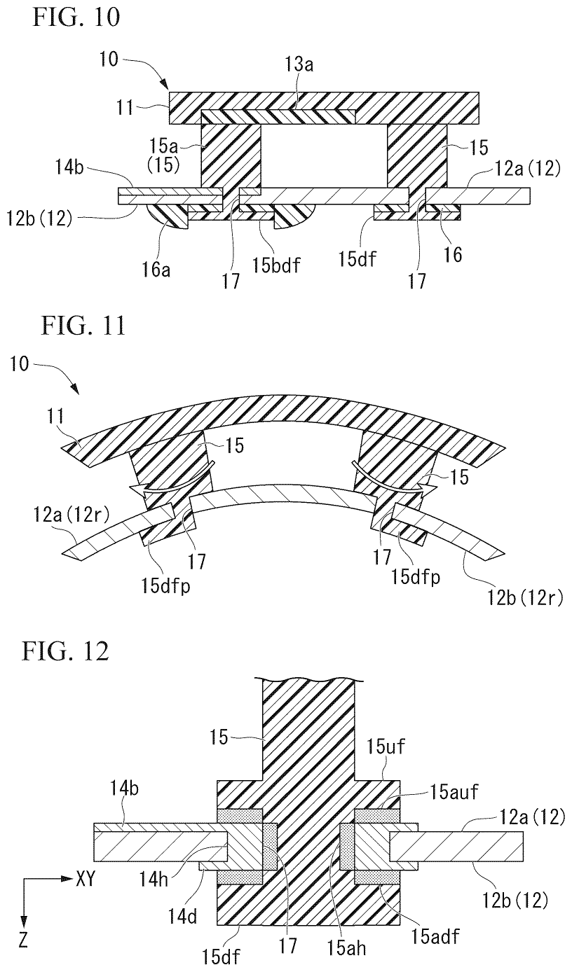

FIG. 10 is a sectional view schematically illustrating a modified example of the capacitance sensor according to the present embodiment.

In this modified example, the right pillar 15 has the same configuration as the pillar 15 including the adhesion portion 16 illustrated in FIGS. 2 and 6 as illustrated in FIG. 10. The left pillar 15 is the pillar wire 15a as a whole and connects the flexible wire 13a and the board wire 14b over the layers. In the left through hole 17, a flexible member having the same conductivity as the flexible wire 13a extends continuously from the end of the pillar wire 15a. An overlap portion 15bdf is formed of a flexible member having the same conductivity as the flexible wire 13a.

That is, the flexible wire 13a, the pillar wire 15a, and the overlap portion 15bdf are formed as a unified body. The overlap portion 15bdf is connected to the rear surface 12b of the board 12 via a conductive adhesion portion 16a. The conductive adhesion portion 16a is formed to extend to a position outside of the overlap portion 15bdf in the radial direction.

In this modified example, the board wire 14b is disposed on the surface 12a, but the board wire may be disposed on the rear surface 12b and may be connected to the pillar wire 15a via the overlapping portion 15bdf and the conductive adhesion portion 16a having conductivity.

FIG. 11 is a sectional view schematically illustrating a modified example of the capacitance sensor according to the present embodiment.

In this modified example, a board 12r has a curved shape as illustrated in FIG. 11. In this modified example, a partial overlap portion 15dfp is formed in only a part in the circumferential direction unlike the overlap portion 15df illustrated in FIGS. 2 and 6. In this drawing, the electrodes 13 and 14 and the wires 13a, 14a, 14b, and 15a are not illustrated.

The partial overlap portion 15dfp extends substantially in a linear shape in one radial direction from the center axis of the through hole 17. The length of the partial overlap portion 15dfp in the radial direction is equal to the length in the radial direction of the overlap portion 15df illustrated in FIGS. 2 and 6.

As illustrated in FIG. 11, the partial overlap portions 15dfp formed in the neighboring pillars 15 can extend in the opposite directions. In this modified example, the partial overlap portions 15dfp formed in the neighboring pillars 15 can be formed to get farther from the center between the two pillars 15 when the surface 12a of the board 12 located in the vicinity of the center between the two pillars 15 protrudes toward the electrode inclusion portion 11. Accordingly, when an external load F is applied such that the flexible member 15A peels off from the board 12r, it is possible to make it difficult for the flexible member 15A to depart from the through hole 17.

In this modified example, when a plurality of pillars 15 include the partial overlap portion 15dfp, directions in which the partial overlap portion 15dfp extend can preferably be different in the neighboring pillars 15. Accordingly, it is similarly possible to prevent all the partial overlap portions 15dfp from departing from the through holes 17 regardless of the direction of the applied external load F.

When a plurality of pillars 15 includes the partial overlap portion 15dfp, directions in which the partial overlap portion 15dfp extend can also be random.

When the partial overlap portion 15dfp has a size capable of passing through the corresponding through hole 17, the partial overlap portion 15dfp can be bonded to the rear surface 12b of the board 12 using the adhesion portion 16. Alternatively, it is possible to reduce the number of manufacturing steps by performing assembly such that the partial overlap portion 15dfp passes through the through hole 17 at the time of assembly.

In the present embodiment, a flat rigid board is used as the board 12, but the following configuration may be employed.

As the board, a configuration including a stretchable wire which can be directly attached on a surface of a human body or the like, a configuration including a metal frame as a part of an outer surface of a housing of a robot, a configuration including functional flexible fabric formed of fiber, a surface of an electronic device, a surface of a functional furniture piece such as a sofa, a bed, or a cushion, a shoe insole, a handle of a vehicle, a motorbike, a bicycle, or the like may be employed.

A capacitance sensor according to a second embodiment of the present invention will be described below with reference to the drawings.

FIG. 12 is a sectional view schematically illustrating the capacitance sensor according to the present embodiment. The present embodiment is different from the first embodiment in regard to the arrangement of a cover portion and a wire. The constituents corresponding to those in the first embodiment will be referred to by the same reference signs, and description thereof will be omitted.

A capacitance sensor 10 according to the present embodiment includes a cover portion 15uf as illustrated in FIG. 12.

The cover portion 15uf is formed in the vicinity of an end of the pillar 15. The cover portion 15uf is in contact with the outer edge of the through hole 17 on the surface 12a of the board 12. The cover portion 15uf is present at the outer edge of the through hole 17 along the surface 12a of the board 12. The cover portion 15uf is formed in a flange shape extending from the pillar 15. The cover portion 15uf is formed in a flange shape extending from the through hole 17.

When the diameter of the through hole 17 is larger than the diameter of the pillar 15, the cover portion 15uf may not be provided.

The diameter of the cover portion 15uf is larger than the diameter of the through hole 17. The diameter of the cover portion 15uf is larger than the diameter of the pillar 15. The diameter of the cover portion 15uf is equal to or different from the diameter of the overlap portion 15df. The diameter of the cover portion 15uf may be smaller than the diameter of the overlap portion 15df. The diameter of the cover portion 15uf may be larger than the diameter of the overlap portion 15df.

The thickness of the cover portion 15uf is equal to or different from the thickness of the overlap portion 15df. The thickness of the cover portion 15uf may be larger than the thickness of the overlap portion 15df. The thickness of the cover portion 15uf may be smaller than the thickness of the overlap portion 15df.

The cover portion 15uf has the same thickness in the circumferential direction as a whole. The cover portion 15uf has the same thickness in the radial direction as a whole.

The cover portion 15uf is formed as a unified body with the pillar 15. The cover portion 15uf is formed of the flexible member 15A which is the same material as the pillar 15. When a flexible pillar wire 15a is formed in the pillar 15, the cover portion 15uf may include a part formed of the same material as the pillar wire 15a.

The cover portion 15uf may be bonded to the surface 12a of the board 12 using the adhesion portion 16. The cover portion 15uf is bonded to the surface 12a of the board 12 using the adhesion portion 16 in all the pillars 15. Alternatively, the cover portion 15uf does not have to be bonded to the surface 12a of the board 12 in some of the plurality of pillars 15.

In the present embodiment, electrical connection between the flexible member 15A and the board 12 is achieved in the vicinity of the through hole 17. A deformable conductive part is formed of the flexible member 15A between the flexible member 15A and the board 12, and the electrical connection is maintained even when the flexible member 15A is deformed.

Specifically, a board surface wire 14b, a hole inner periphery wire 14h, and a board rear wire 14d (a conductive portion) are formed in the board 12 as illustrated in FIG. 12.

The board surface wire 14b is formed on the surface 12a which is the outer edge of the through hole 17.

The board rear wire 14d is formed on the rear surface 12b which is the outer edge of the through hole 17.

The hole inner periphery wire 14h is formed on the inner circumferential surface of the through hole 17. Both ends of the hole inner periphery wire 14h in the axial direction of the through hole 17 are connected to the board surface wire 14b and the board rear wire 14d. Both ends of the hole inner periphery wire 14h in the axial direction of the through hole 17 may not be connected to the board surface wire 14b and the board rear wire 14d as a whole.

The board surface wire 14b, the hole inner periphery wire 14h, and the board rear wire 14d are electrically connected to each other. The board surface wire 14b and the board rear wire 14d are electrically connected via the hole inner periphery wire 14h.

Similarly, a cover portion wire (a flexible wire, a conductor) 15auf, an intra-hole wire (a flexible wire, a conductor) 15ah, and an overlap portion wire (a flexible wire, a conductor) 15adf are formed in the pillar 15. The pillar wire 15a is formed in the pillar 15 but is not illustrated herein.

The cover portion wire 15auf is formed in the cover portion 15uf. The cover portion wire 15auf is formed on a flange surface of the cover portion 15uf at a position facing the surface 12a.

The intra-hole wire 15ah is formed on an outer circumferential surface of the flexible member 15A located inside of the through hole 17.

The overlap portion wire 15adf is formed in the overlap portion 15df. The overlap portion wire 15adf is formed on a flange surface of the overlap portion 15df at a position facing the rear surface 12b.

The cover portion wire 15auf, the intra-hole wire 15ah, and the overlap portion wire 15adf are electrically connected to each other. The cover portion wire 15auf and the overlap portion wire 15adf are electrically connected via the intra-hole wire 15ah. Alternatively, the cover portion wire 15auf, the intra-hole wire 15ah, and the overlap portion wire 15adf may be connected to each other via a pillar wire 15a which is not illustrated.

Alternatively, the cover portion 15uf, the overlap portion 15df, and an end of the pillar 15 may be formed of the same conductive material.

The board surface wire 14b and the cover portion wire 15auf are disposed to face each other. The board surface wire 14b and the cover portion wire 15auf are in contact with each other when an external load F is not applied. In this case, the board surface wire 14b and the cover portion wire 15auf are in contact with each other in planes parallel to the surface 12a. The board surface wire 14b and the cover portion wire 15auf in contact with each other are electrically connected to each other.

The hole inner periphery wire 14h and the intra-hole wire 15ah are disposed to face each other. The hole inner periphery wire 14h and the intra-hole wire 15ah are in contact with each other when an external load F is not applied. In this case, the hole inner periphery wire 14h and the intra-hole wire 15ah are in contact with each other in cylindrical surfaces around the axis of the through hole 17. The hole inner periphery wire 14h and the intra-hole wire 15ah in contact with each other are electrically connected to each other.

The board rear wire 14d and the overlap portion wire 15adf are disposed to face each other. The board rear wire 14d and the overlap portion wire 15adf are in contact with each other when an external load F is not applied. In this case, the board rear wire 14d and the overlap portion wire 15adf are in contact with each other in planes parallel to the rear surface 12b. The board rear wire 14d and the overlap portion wire 15adf in contact with each other are electrically connected to each other.

In a state in which an external load F is not applied, the board surface wire 14b and the cover portion wire 15auf are electrically connected, the hole inner periphery wire 14h and the intra-hole wire 15ah are electrically connected, and the board rear wire 14d and the overlap portion wire 15adf are electrically connected. The board surface wire 14b and the cover portion wire 15auf, the hole inner periphery wire 14h and the intra-hole wire 15ah, and the board rear wire 14d and the overlap portion wire 15adf have contact resistances.

Here, it is assumed that the contact resistances in the state in which an external load F is not applied are used as reference values. Then, when the cover portion wire 15auf, the intra-hole wire 15ah, and the overlap portion wire 15adf are compressed, the contact resistances thereof are smaller than the reference values. Compression of the cover portion wire 15auf, the intra-hole wire 15ah, and the overlap portion wire 15adf occurs, for example, when an external load F is applied and the flexible member 15A is deformed.

When an external load F is applied and the flexible member 15A is deformed, one or more pairs of the board surface wire 14b and the cover portion wire 15auf, the hole inner periphery wire 14h and the intra-hole wire 15ah, and the board rear wire 14d and the overlap portion wire 15adf may be separated from each other to cause electrical disconnection. This deformation will be described below.

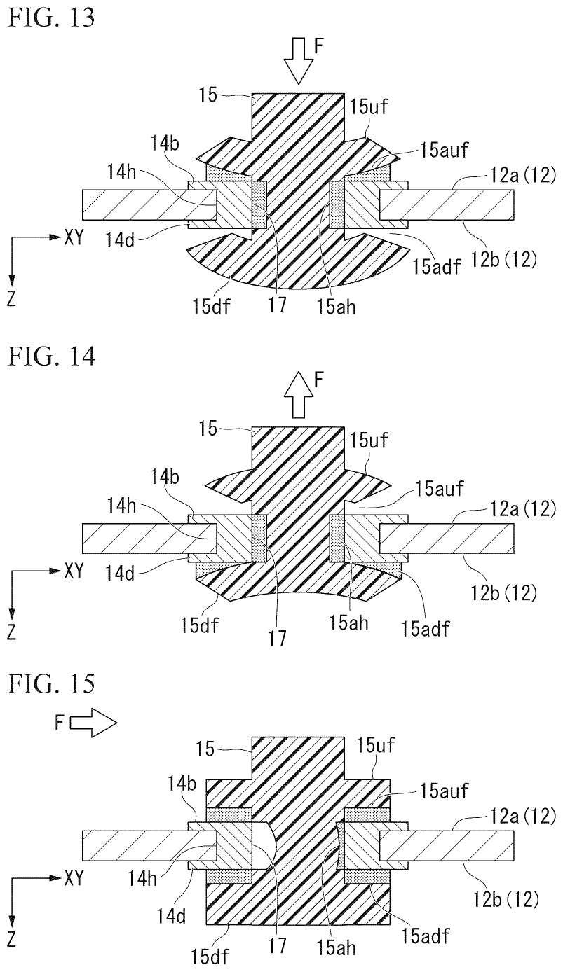

FIG. 13 is a sectional view schematically illustrating a state in which an external load F is applied to the capacitance sensor according to the present embodiment. In FIG. 13, a direction in which the electrode inclusion portion 11 moves toward the surface 12a of the board 12 is defined as a +Z direction. A direction parallel to the surface 12a of the board 12 is defined as a +XY direction. The +XY direction is one direction out of directions parallel to the surface 12a.

When an external load F in the +Z direction is applied to the capacitance sensor 10 as illustrated in FIG. 13, the electrode inclusion portion 11 is deformed in a direction in which the electrode inclusion portion 11 approaches the surface 12a of the board 12. Therewith, the pillar 15 is pressed in the +Z direction. Then, the cover portion 15uf and the overlap portion 15df are pressed in the +Z direction. At this time, since the board 12 is not deformed, the cover portion 15uf and the overlap portion 15df are deformed such that the center therebetween moves in the +Z direction.

At this time, the cover portion 15uf is deformed such that it is pressed on the surface 12a of the board 12 due to the external load F in the +Z direction. Through deformation of the cover portion 15uf due to the external load F in the +Z direction, the cover portion wire 15auf is pressed on the board surface wire 14b. The cover portion wire 15auf is compressed, and a density of conductive particles is increased.

Similarly, the overlap portion 15df is deformed in the direction in which it is separated from the rear surface 12b of the board 12 due to due to the external load F in the +Z direction. Through deformation of the overlap portion 15df due to the external load F in the +Z direction, the overlap portion wire 15adf is stretched such that it is peeled off from the board rear wire 14d. The overlap portion wire 15adf is pulled and extended, and the density of conductive particles is decreased.

At this time, a frictional force is generated such that the hole inner periphery wire 14h and the intra-hole wire 15ah move relatively in the +Z direction due to the external load F in the +Z direction. Even when the hole inner periphery wire 14h and the intra-hole wire 15ah are shifted in the +Z direction, the contact area almost does not change.

When the external load F is smaller than a threshold value, the resistance value of the compressed cover portion wire 15auf is slightly decreased due to the deformation of the flexible member 15A. At the same time, the contact resistance between the compressed cover portion wire 15auf and the board surface wire 14b is slightly decreased.

Similarly, the resistance value of the pulled and extended overlap portion wire 15adf is slightly increased due to the deformation of the flexible member 15A. At the same time, the contact resistance between the pulled and extended overlap portion wire 15adf and the board rear wire 14d is slightly increased.

Even when the relative position is slightly shifted due to the deformation of the flexible member 15A, the contact resistance between the hole inner periphery wire 14h and the intra-hole wire 15ah almost does not change.

In this way, when the external load F is smaller than the threshold value, a decrease in resistance between the cover portion wire 15auf and the board surface wire 14b and an increase in resistance between the overlap portion wire 15adf and the board rear wire 14d are cancelled out. Accordingly, an electrical connection state almost does not change and is not greatly affected.

On the other hand, when an external load F in the +Z direction larger than the threshold value is applied, the resistance of the compressed cover portion wire 15auf is further decreased due to the deformation of the flexible member 15A. At the same time, the contact resistance between the compressed cover portion wire 15auf and the board surface wire 14b is further decreased.

Similarly, the overlap portion 15df is peeled off from the rear surface 12b of the board 12 due to the external load F in the +Z direction larger than the threshold value. Through peeling-off of the overlap portion 15df due to the external load F in the +Z direction, the overlap portion wire 15adf is separated from the board rear wire 14d. In FIG. 13, the peeled-off part of the overlap portion wire 15adf does not contribute to electrical connection and thus is not illustrated.

The relative position between the hole inner periphery wire 14h and the intra-hole wire 15ah is slightly shifted due to the external load F in the +Z direction larger than the threshold value. The contact resistance between the hole inner periphery wire 14h and the intra-hole wire 15ah almost does not change due to the deformation of the flexible member 15A.

When an external load F in the +Z direction is larger than the threshold value, the decrease in resistance value between the cover portion wire 15auf and the board surface wire 14b and the increase in resistance value due to separation between the overlap portion wire 15adf and the board rear wire 14d are mostly cancelled out. Accordingly, the electrical connection state almost does not change and is not greatly affected.

In the capacitance sensor according to the present embodiment, even when an external load F in the +Z direction is applied, a change in resistance due to deformation of the flexible member 15A is cancelled out by various parts, and the electrical connection state is not greatly affected. Accordingly, it is possible to measure the external load F with stable detection characteristics and high durability maintained.

FIG. 14 is a sectional view schematically illustrating a state in which an external load F is applied to the capacitance sensor according to the present embodiment.

When an external load F in the −Z direction is applied to the capacitance sensor 10 as illustrated in FIG. 14, the electrode inclusion portion 11 is deformed in a direction in which the electrode inclusion portion 11 is separated from the surface 12a of the board 12. Therewith, the pillar 15 is pulled and extended in the −Z direction. Then, the cover portion 15uf and the overlap portion 15df are pulled and extended in the −Z direction. At this time, since the board 12 is not deformed, the cover portion 15uf and the overlap portion 15df are deformed such that the center therebetween moves in the −Z direction.

At this time, the cover portion 15uf is deformed such that it is separated from the surface 12a of the board 12 due to the external load F in the −Z direction. Through deformation of the cover portion 15uf due to the external load F in the −Z direction, the cover portion wire 15auf is stretched to be pulled and peeled off from the board surface wire 14b. The cover portion wire 15auf is pulled and extended, and the density of conductive particles is decreased.

Similarly, the overlap portion 15df is deformed in the direction in which it is pressed on the rear surface 12b of the board 12 due to due to the external load F in the −Z direction. Through deformation of the overlap portion 15df due to the external load Fin the −Z direction, the overlap portion wire 15adf is pressed on the board rear wire 14d. The overlap portion wire 15adf is compressed, and the density of conductive particles is increased.

At this time, a frictional force is generated such that the hole inner periphery wire 14h and the intra-hole wire 15ah move relatively in the −Z direction due to the external load F in the −Z direction. Even when the hole inner periphery wire 14h and the intra-hole wire 15ah are shifted in the −Z direction, the contact area almost does not change.

When the external load F is smaller than a threshold value, the resistance value of the pulled and extended cover portion wire 15auf is slightly increased due to the deformation of the flexible member 15A. At the same time, the contact resistance between the cover portion wire 15auf with an increased volume and the board surface wire 14b is slightly increased.

Similarly, the resistance value of the compressed overlap portion wire 15adf is slightly decreased due to the deformation of the flexible member 15A. At the same time, the contact resistance between the pressed overlap portion wire 15adf and the board rear wire 14d is slightly decreased.

Even when the relative position is slightly shifted due to the deformation of the flexible member 15A, the contact resistance between the hole inner periphery wire 14h and the intra-hole wire 15ah almost does not change.

In this way, when the external load F is smaller than the threshold value, the increase in resistance value between the cover portion wire 15auf and the board surface wire 14b and the decrease in resistance value between the overlap portion wire 15adf and the board rear wire 14d are cancelled out. Accordingly, the electrical connection state almost does not change and is not greatly affected.

On the other hand, when an external load F in the −Z direction larger than the threshold value is applied, the cover portion wire 15auf is peeled off from the surface 12a of the board 12 due to the deformation of the flexible member 15A, and the resistance value thereof is further decreased. At the same time, the cover portion wire 15auf is separated from the board surface wire 14b. In FIG. 14, the peeled-off part of the cover portion wire 15auf does not contribute to electrical connection and thus is not illustrated.

Similarly, the overlap portion 15df is pressed on the rear surface 12b of the board 12 due to the external load F in the −Z direction larger than the threshold value. Through the compression of the overlap portion 15df due to the external load F in the −Z direction, the resistance value of the overlap portion wire 15adf is further decreased. At the same time, the contact resistance between the compressed overlap portion wire 15adf and the board rear wire 14d is further decreased.

The relative position between the hole inner periphery wire 14h and the intra-hole wire 15ah is slightly shifted due to the external load F in the −Z direction larger than the threshold value. The contact resistance between the hole inner periphery wire 14h and the intra-hole wire 15ah almost does not change due to the deformation of the flexible member 15A.

When an external load F in the −Z direction is larger than the threshold value, the increase in resistance value between the cover portion wire 15auf and the board surface wire 14b and the decrease in resistance value due to separation between the overlap portion wire 15adf and the board rear wire 14d are mostly cancelled out. Accordingly, the electrical connection state almost does not change and is not greatly affected.

In the capacitance sensor according to the present embodiment, even when an external load F in the −Z direction is applied, the change in resistance value due to deformation of the flexible member 15A is cancelled out by various parts, and the electrical connection state is not greatly affected. Accordingly, it is possible to measure the external load F with stable detection characteristics and high durability maintained.

FIG. 15 is a sectional view schematically illustrating a state in which an external load F is applied to the capacitance sensor according to the present embodiment.

When an external load F in the +XY direction is applied to the capacitance sensor 10 as illustrated in FIG. 15, the electrode inclusion portion 11 is deformed in the +XY direction along the surface 12a of the board 12. Therewith, the pillar 15 is pulled and extended in the +XY direction. Then, the cover portion 15uf and the overlap portion 15df are pulled and extended in the +XY direction. At this time, since the board 12 is not deformed, the cover portion 15uf and the overlap portion 15df are deformed to move in the +XY direction.

At this time, the cover portion 15uf and the overlap portion 15df are deformed to move in the +XY direction along the surface 12a of the board 12 due to the external load F in the +XY direction.

Through deformation of the cover portion 15uf due to the external load F in the +XY direction, the cover portion wire 15auf moves relatively in the +XY direction along the board surface wire 14b.

Similarly, through deformation of the overlap portion 15df due to the external load F in the +XY direction, the overlap portion wire 15adf moves relatively in the +XY direction along the board rear wire 14d. Since the cover portion wire 15auf and the overlap portion wire 15adf are not compressed and are not pulled and extended, the density of conductive particles does not change. The resistance value between the cover portion wire 15auf and the board surface wire 14b and the resistance value between the overlap portion wire 15adf and the board rear wire 14d almost do not change.

At this time, the intra-hole wire 15ah is pressed in the +XY direction due to the external load F in the +XY direction. Then, the part of the intra-hole wire 15ah corresponding to the +XY direction of the circumferential direction is pressed to the hole inner periphery wire 14h. The part of the intra-hole wire 15ah corresponding to the reverse direction to the +XY direction in the circumferential direction is pulled and extended to be peeled off from the hole inner periphery wire 14h.

In the intra-hole wire 15ah, the density of conductive particles is increased in the compressed part, and the density of conductive particles is decreased in the pulled and extended part. Accordingly, in the intra-hole wire 15ah, the resistance value in the compressed part is decreased, and the resistance value in the pulled and extended part is increased.

When the external force F in the +XY direction is smaller than the threshold value, the change in resistance value in the intra-hole wire 15ah due to deformation of the flexible member 15A is cancelled out.

In the cover portion wire 15auf and the overlap portion wire 15adf, the change in resistance value almost does not occur.

When the external force F in the +XY direction is larger than the threshold value, similarly, the part of the intra-hole wire 15ah corresponding to the +XY direction in the circumferential direction is further pressed to the hole inner periphery wire 14h. The part of the intra-hole wire 15ah corresponding to the reverse direction to the +XY direction in the circumferential direction is pulled and peeled off to be separated from the hole inner periphery wire 14h. In the intra-hole wire 15ah, the resistance value in the pressed part is decreased, and the contact area in the peeled-off part is zero. In FIG. 15, the peeled-off part of the intra-hole wire 15ah does not contribute to electrical connection and thus is not illustrated.

When the external force F in the +XY direction is larger than the threshold value, the cover portion wire 15auf moves relatively in the +ZY direction along the board surface wire 14b. The overlap portion wire 15adf moves relatively in the +XY direction along the board rear wire 14d. However, the resistance value between the cover portion wire 15auf and the board surface wire 14b and the resistance value between the overlap portion wire 15adf and the board rear wire 14d almost do not change.

In the capacitance sensor according to the present embodiment, even when an external load F in the +XY direction is applied, the change in resistance value due to deformation of the flexible member 15A is cancelled out by various parts, and the electrical connection state is not greatly affected. Accordingly, it is possible to measure the external load F with stable detection characteristics maintained.

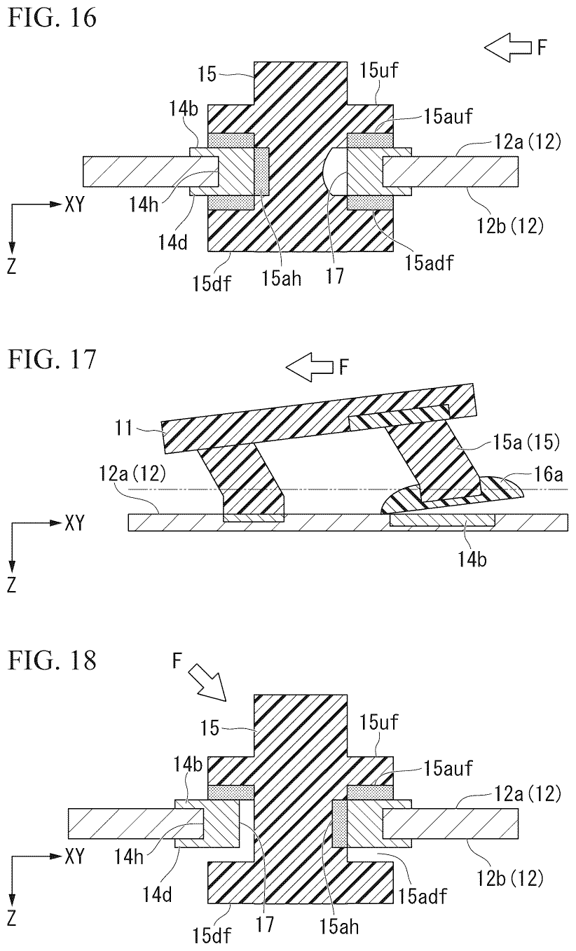

FIG. 16 is a sectional view schematically illustrating a state in which an external load F is applied to the capacitance sensor according to the present embodiment.

When an external load F in the −XY direction is applied to the capacitance sensor 10 as illustrated in FIG. 16, the deformation direction is opposite to that when an external load F in the +XY direction is applied, and the others are the same. Accordingly, the change in resistance value due to deformation of the flexible member 15A is cancelled out by various parts, and the electrical connection state is not greatly affected. Accordingly, it is possible to accurately measure the external load F with stable detection characteristics and high durability maintained.

FIG. 17 is a sectional view schematically illustrating a state in which an external load F is applied to a capacitance sensor according to the related art.

When a large external load F in the −XY direction is applied to the capacitance sensor according to the related art as illustrated in FIG. 17, the conductive adhesion portion 16a is peeled off. Since there is no conductive part other than the conductive adhesion portion 16a, electrical connection is cut off. On the other hand, with the capacitance sensor 10 according to the present embodiment, it is possible to prevent disconnection.

FIG. 18 is a sectional view schematically illustrating a state in which an external load F is applied to the capacitance sensor according to the present embodiment.

When an external load F including a +Z component and a +XY component is applied to the capacitance sensor 10 as illustrated in FIG. 18, deformation in the direction in which the electrode inclusion portion 11 approaches the surface 12a of the board 12 and deformation in the +XY direction in which the electrode inclusion portion 11 moves along the surface 12a of the board 12 occur simultaneously. Therewith, the pillar 15 is compressed in the +Z direction and is pulled and extended in the +XY direction.

Then, since the board 12 is not deformed, the cover portion 15uf and the overlap portion 15df are deformed such that the center therebetween is pressed in the +Z direction, and the cover portion 15uf and the overlap portion 15df are pulled and extended in the +XY direction. At the same time, the intra-hole wire 15ah is pressed in the +XY direction. In FIG. 18, the peeled-off parts of the intra-hole wire 15ah and the overlap portion wire 15adf do not contribute to electrical connection and thus are not illustrated.

When the external load F including a +Z component and a +XY component is applied, an influence of the application of the external load F in the +Z direction and an influence of the application of the external load F in the +XY direction occur simultaneously. As a result, the decrease in resistance value between the cover portion wire 15auf and the board surface wire 14b, the increase in resistance value between the overlap portion wire 15adf and the board rear wire 14d, and the change in resistance value between the hole inner periphery wire 14h and the intra-hole wire 15ah are mostly cancelled out. Accordingly, an electrical connection state changes slightly and is not greatly affected.

This is because the magnitude of the external load F including the +Z component and the +XY component is not affected by the magnitude of the threshold value serving as a peeling limit. Accordingly, it is possible to measure the external load F with stable detection characteristics and high durability maintained.

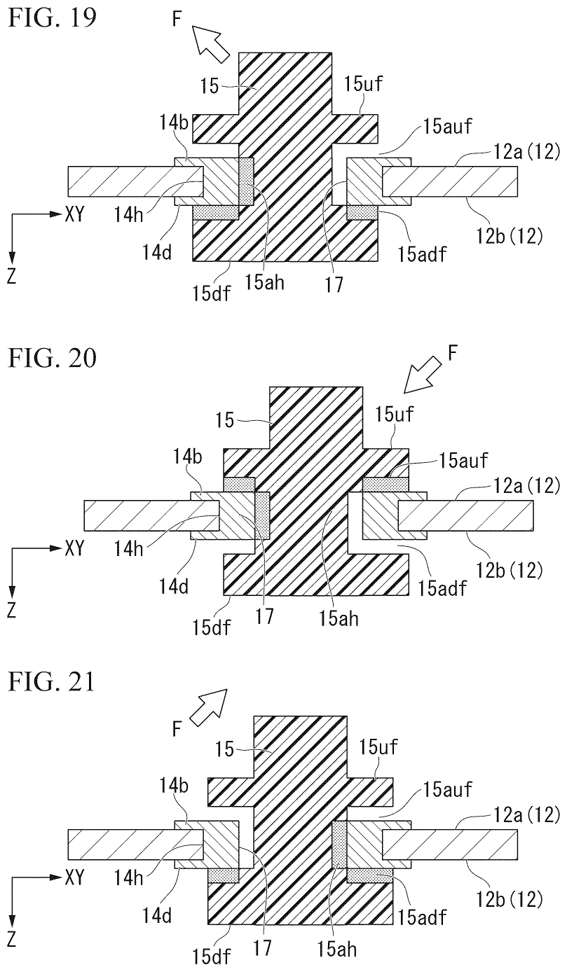

FIG. 19 is a sectional view schematically illustrating a state in which an external load F is applied to the capacitance sensor according to the present embodiment.

When an external load F including a −Z component and a −XY component is applied to the capacitance sensor 10 as illustrated in FIG. 19, deformation in the direction in which the electrode inclusion portion 11 is separated from the surface 12a of the board 12 and deformation in the −XY direction in which the electrode inclusion portion 11 moves along the surface 12a of the board 12 occur simultaneously. Therewith, the pillar 15 is pulled and extended in the −Z direction and is pulled and extended in the −XY direction.

Then, since the board 12 is not deformed, the cover portion 15uf and the overlap portion 15df are deformed such that the center therebetween is pulled and extended in the −Z direction, and the cover portion 15uf and the overlap portion 15df are pulled and extended in the −XY direction. At the same time, the intra-hole wire 15ah is pressed in the −XY direction. In FIG. 19, the peeled-off parts of the intra-hole wire 15ah and the cover portion wire 15auf do not contribute to electrical connection and thus are not illustrated.

When the external load F including a −Z component and a −XY component is applied, an influence of the application of the external load F in the −Z direction and an influence of the application of the external load F in the −XY direction occur simultaneously. As a result, the increase in resistance value between the cover portion wire 15auf and the board surface wire 14b, the decrease in resistance value between the overlap portion wire 15adf and the board rear wire 14d, and the change in resistance value between the hole inner periphery wire 14h and the intra-hole wire 15ah are mostly cancelled out. Accordingly, an electrical connection state changes slightly and is not greatly affected.

This is because the magnitude of the external load F including the −Z component and the −XY component is not affected by the magnitude of the threshold value serving as a peeling limit. Accordingly, it is possible to measure the external load F with stable detection characteristics and high durability maintained.

FIG. 20 is a sectional view schematically illustrating a state in which an external load F is applied to the capacitance sensor according to the present embodiment.

When an external load F including a +Z component and a −XY component is applied to the capacitance sensor 10 as illustrated in FIG. 20, deformation in the direction in which the electrode inclusion portion 11 approaches the surface 12a of the board 12 and deformation in the −XY direction in which the electrode inclusion portion 11 moves along the surface 12a of the board 12 occur simultaneously. Therewith, the pillar 15 is pulled and extended in the +Z direction and is pulled and extended in the −XY direction.

Then, since the board 12 is not deformed, the cover portion 15uf and the overlap portion 15df are deformed such that the center therebetween is pulled and extended in the +Z direction, and the cover portion 15uf and the overlap portion 15df are pulled and extended in the −XY direction. At the same time, the intra-hole wire 15ah is pressed in the −XY direction. In FIG. 20, the peeled-off parts of the intra-hole wire 15ah and the overlap portion wire 15adf do not contribute to electrical connection and thus are not illustrated.

When the external load F including a +Z component and a −XY component is applied, an influence of the application of the external load F in the +Z direction and an influence of the application of the external load F in the −XY direction occur simultaneously. As a result, the decrease in resistance value between the cover portion wire 15auf and the board surface wire 14b, the increase in resistance between the overlap portion wire 15adf and the board rear wire 14d, and the change in resistance between the hole inner periphery wire 14h and the intra-hole wire 15ah are mostly cancelled out. Accordingly, an electrical connection state changes slightly and is not greatly affected.

This is because the magnitude of the external load F including the +Z component and the −XY component is not affected by the magnitude of the threshold value serving as a peeling limit. Accordingly, it is possible to measure the external load F with stable detection characteristics and high durability maintained.

FIG. 21 is a sectional view schematically illustrating a state in which an external load F is applied to the capacitance sensor according to the present embodiment.

When an external load F including a +−Z component and a +XY component is applied to the capacitance sensor 10 as illustrated in FIG. 21, deformation in the direction in which the electrode inclusion portion 11 is separated from the surface 12a of the board 12 and deformation in the +XY direction in which the electrode inclusion portion 11 moves along the surface 12a of the board 12 occur simultaneously. Therewith, the pillar 15 is pulled and extended in the −Z direction and is pulled and extended in the +XY direction.

Then, since the board 12 is not deformed, the cover portion 15uf and the overlap portion 15df are deformed such that the center therebetween is pulled and extended in the −Z direction, and the cover portion 15uf and the overlap portion 15df are pulled and extended in the +XY direction. At the same time, the intra-hole wire 15ah is pressed in the +XY direction. In FIG. 21, the peeled-off parts of the intra-hole wire 15ah and the cover portion wire 15auf do not contribute to electrical connection and thus are not illustrated.

When the external load F including a −Z component and a +XY component is applied, an influence of the application of the external load F in the −Z direction and an influence of the application of the external load F in the +XY direction occur simultaneously. As a result, the increase in resistance value between the cover portion wire 15auf and the board surface wire 14b, the decrease in resistance value between the overlap portion wire 15adf and the board rear wire 14d, and the change in resistance value between the hole inner periphery wire 14h and the intra-hole wire 15ah are mostly cancelled out. Accordingly, an electrical connection state changes slightly and is not greatly affected.

This is because the magnitude of the external load F including the −Z component and the +XY component is not affected by the magnitude of the threshold value serving as a peeling limit. Accordingly, it is possible to measure the external load F with stable detection characteristics and high durability maintained.

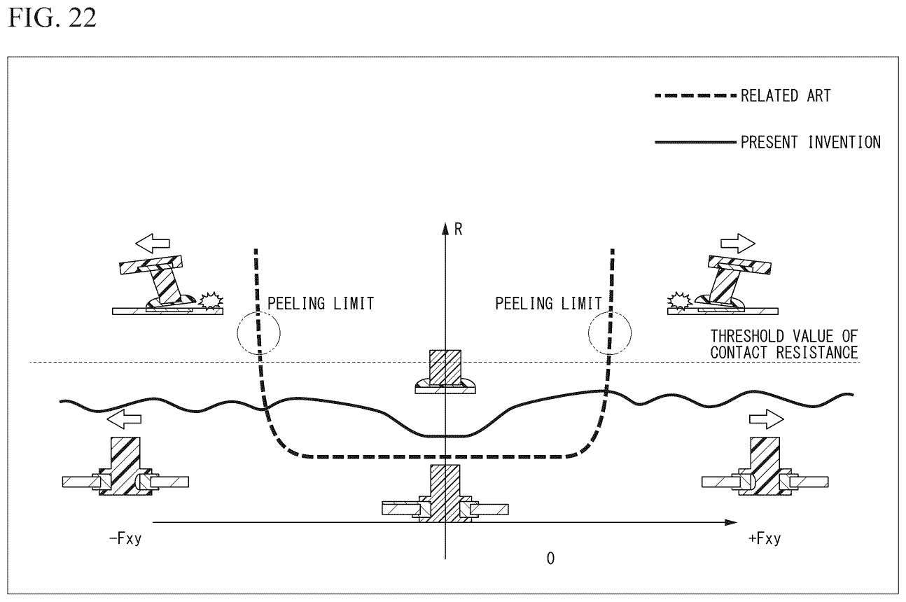

FIG. 22 is a graph illustrating a relationship between an external force and a resistance value in the capacitance sensor according to the present embodiment.

In FIG. 22, the vertical axis represents a resistance value R. The horizontal axis represents a change in magnitude of an external load (an external force) in the +XY direction. In the horizontal axis of FIG. 22, the magnitude of the applied external load F changes from −Fxy to +Fxy via an origin O from left to right. At the origin O, the external load F in the +XY direction is zero.

In the capacitance sensor 10 according to the present embodiment, the resistance value R when the direction of the external load F changes from the −XY direction to the +XY direction along the horizontal axis increases or decreases slightly but is an almost constant value as illustrated in FIG. 22. The peeling limit is not exceeded with the illustrated magnitude of the external load F. The threshold value for the contact resistance is not exceeded with the illustrated magnitude of the external load F.

On the other hand, in the capacitance sensor according to the related art, it can be seen from FIG. 22 that the resistance value R when the direction of the external load F changes from the −XY direction to the +XY direction along the horizontal axis is lower than that of the capacitance sensor 10 according to the present embodiment in the vicinity of the origin O, but the resistance value R increases rapidly in the −Fxy direction and the +Fxy direction when the external load F increases. This indicates that =, when the magnitude of the external load F approaches a value with which peeling is caused, the resistance value R exceeds the threshold value for the contact resistance and increases rapidly.

This indicates that a contact state can be maintained in one or more places even when an external force is applied to the capacitance sensor 10 according to the present embodiment and a gap is formed between the flexible conductive pillar 15a and the through-hole (through hole) 17 in the board 12.

Here, formation of a gap due to separation between the flexible wire and the board wire serves as a resistance increase factor. Compression of the flexible conductive pillar and a decrease in contact resistance due to pressing of the flexible conductor to the through-hole serve as a resistance decrease factor. In the capacitance sensor 10 according to the present embodiment, a resistance increase and the resistance decrease are cancelled out due to these factors, and the resistance value does not increase greatly and is maintained to be equal to or less than the threshold value.

The present invention can also be realized by individually selecting and combining the configurations of the aforementioned embodiments.

What is claimed is:

1. A capacitance sensor comprising:
a board;
a first electrode provided on a first surface of the board;
a flexible member fixed to the board and having elasticity; and
a second electrode provided in the flexible member to face the first electrode with a gap between the second electrode and the first electrode and configured to detect a capacitance with the first electrode,
wherein the flexible member includes:
an electrode inclusion portion including the second electrode in the electrode inclusion portion and having a gap between the electrode inclusion portion and a surface of the board;
a pillar portion extending between the electrode inclusion portion and the board; and
an overlap portion formed in the pillar portion passing through a through hole penetrating the board and overlapping an outer edge portion of the through hole on a second surface opposite to the first surface of the board.

2. The capacitance sensor according to claim 1,
wherein the flexible member is formed of a dielectric.

3. The capacitance sensor according to claim 1,
wherein the board includes a conductive portion, and
the pillar portion includes a conductor connecting the second electrode and the conductive portion.

4. The capacitance sensor according to claim 1,
wherein the pillar portion includes a cover portion covering the outer edge portion of the through hole on the first surface of the board.

5. The capacitance sensor according to claim 3,
wherein the conductive portion is provided on at least one of an inner circumferential surface of the through hole in the board, the outer edge portion of the through hole on the first surface of the board, and the outer edge portion of the through hole on the second surface of the board and is electrically connected to the conductor of the pillar portion.

6. The capacitance sensor according to claim 1,
wherein the overlap portion is formed either over an entire outer edge of the through hole or a part of the outer edge in a circumferential direction of the through hole.

7. The capacitance sensor according to claim 1,
wherein a plurality of pillar portions are formed, and
a plurality of through holes are formed.
